(19) United States
(12) Patent Application Publication
(10) Pub. No.: US 2026/0041017 A1
(43) Pub. Date: Feb. 5, 2026

(54) MICROELECTRONICS DEVICE PACKAGE WITH ISOLATION AND CERAMIC INTERPOSER FORMING THERMAL PAD

(71) Applicant: Texas Instruments Incorporated, Dallas, TX (US)

(72) Inventors: Woochan Kim, San Jose, CA (US); Yi Yan, San Jose, CA (US); Makoto Shibuya, Tokyo (JP)

(21) Appl. No.: 18/790,493

(22) Filed: Jul. 31, 2024

(51) Int. Cl. H01L 23/495; H01L 23/00; H01L 23/31; H01L 23/373; H01L 25/00; H01L 25/065

(52) U.S. Cl. CPC H01L 23/49575; H01L 23/3107; H01L 23/3731; H01L 25/0655; H01L 25/50; H01L 23/49555; H01L 24/32; H01L 24/48; H01L 24/73; H01L 2224/32225; H01L 2224/48137; H01L 2224/48245; H01L 2224/73265

(57) ABSTRACT

A microelectronic device package includes: a package substrate having a first set of leads spaced from a first die pad configured for mounting semiconductor devices, and a second set of leads spaced from a second die pad configured for mounting additional semiconductor devices, the first die pad and the first set of leads spaced from the second die pad and the second set of leads. Semiconductor devices are mounted to the first die pad and second die pad. A ceramic interposer is mounted to the package substrate in thermal contact with at least the first die pad. Mold compound covers the semiconductor devices, a portion of the ceramic interposer, and portions of the first set and the second set of leads.

### TECHNICAL FIELD

This disclosure relates generally to microelectronic device packages, and more particularly to microelectronic device packages including semiconductor dies mounted on a package substrate with isolation.

### BACKGROUND

Processes for producing microelectronic device packages include mounting one or more semiconductor dies to a package substrate and subsequently covering the electronic devices with a dielectric material, such as a mold compound, to form packaged devices.

Incorporating passive components such as capacitors, inductors, and coils with semiconductor devices in a microelectronic device package is often desirable. These microelectronic device packages can be referred to as “multichip modules” or as “system-in-package” or “SIP” devices. Power package applications include packaging multiple devices together in a system using passive components such as resistors, capacitors, inductors and coils with semiconductor dies to increase performance and reduce board area, and to make the microelectronic device package with the passives needed for a normal configuration as a single component, which increases ease of use and reduces board design time. Often a passive component is mounted next to or mounted on or over a completely packaged semiconductor device.

In certain applications, electrical isolation is required between terminals of a microelectronic device package. Some terminals of the microelectronic device package are configured for connection to a first voltage domain, while other terminals of the microelectronic device package are configured for connection to a second voltage domain, the first and second voltage domains having isolated grounds. An example application for a microelectronics device package with isolation is a DC-DC converter for a power supply arranged to deliver power from a voltage supply to a load coupled to an isolated ground. Because the two voltage domains are isolated one from the other, high voltage potentials of tens, hundreds or thousands of volts can occur between terminals coupled to the two voltage domains. To safely transfer current from one voltage domain to the other, for example in the DC-DC converter application, electrical isolation between devices coupled to one domain and devices coupled to the other voltage domain is required. In example DC-DC applications, a transformer can be used, or a capacitive coupling can be used, to transfer energy or signals across an electrical isolation barrier formed within the microelectronics device package. In some applications, a power field effect transistor (FET) can be used as a switch to control current flowing through a primary coil, while current generated in a corresponding secondary coil can be used to create an isolated output voltage for powering a load. In a particular example, a universal serial bus (USB) power delivery (PD) or USB-PD system can be implemented using a microelectronic device package with reinforced electrical isolation to provide the necessary power control functions and including a primary side switch, while a transformer can be provided external to the microelectronic device package to enable implementing an AC-DC USB-PD wall power adapter, or to implement a DC-DC battery supply for a USB-PD port.

Additional requirements to maintain robust isolation between terminals of a microelectronics device package include minimum spacing distance requirements between the terminals coupled to the different voltage domains. One spacing requirement is a minimum creepage distance, which is a minimum distance between exposed terminals at different potentials including the path over the dielectric body of the microelectronics device package. At high voltages, such as up to several thousand volts, skin effect coupling can create an unwanted current leakage path between terminals, reducing the isolation provided by the package. By maintaining a sufficient distance between the terminals, this “creepage” effect current can be reduced or eliminated. Another distance requirement is a minimum clearance distance, which is a minimum distance in air between the terminals coupled to the different voltage domains. If this clearance distance is not great enough, the terminals at different potentials can be coupled by breakdown of the air between the terminals, forming a current arc, so that an unwanted path is created coupling the terminals, and again creating a current leakage path.

In addition, in operation, power devices packaged within the microelectronics device package can require thermal dissipation. In a conventional approach, a conductive die pad, such as a copper, plated copper, or a gold die pad, is part of the package substrate and exposing a surface of the die pad forms a thermal dissipation path. By exposing a surface of the die pad from the mold compound that forms the body of the package, the dies mounted to the die pad have a thermal path to the ambient environment, and forced air, convection, or liquid cooling can be used to further dissipate heat from the die using the conductive thermal pad. However, because the metal die pad is an electrical conductor, the minimum creepage distance requirement also applies to the die pad, which is exposed on a surface of the body of the microelectronics device package, and this creates a need for a larger than desired package size to meet the creepage distance requirement. Increasing package size contradicts the continual need for smaller device packages. Smaller package sizes are always desirable and continue to be needed to reduce board area and increase integration of the devices. Design and manufacture of robust isolation packages with reduced area for power applications continue to be challenging.

### SUMMARY

In a described example, a method includes: mounting semiconductor devices on a device side surface of a first die pad and on the device side surface of a second die pad of a package substrate, the package substrate including a first set of leads spaced from the first die pad, a second set of leads spaced from the first set of leads and the first die pad, and the second die pad spaced from the second set of leads and spaced from the first die pad and the first set of leads. The method continues by forming electrical connections between bond pads on the semiconductor devices and the first set of leads and the second set of leads. The method then continues by mounting a ceramic interposer on an opposite side surface of the package substrate opposite the device side surface, the ceramic interposer mounted to at least one of the first die pad and the second die pad using thermally conductive material. The method then proceeds by covering the semiconductor devices, the electrical connections, the first die pad and the second die pad with mold compound, covering a portion of the ceramic interposer with mold compound, and covering a portion of the first set of leads and a portion of the second set of leads with mold compound. The mold compound forms a body of a microelectronic device package, the ceramic interposer having a surface exposed from the mold compound, and a portion of the first set of leads not covered by the mold compound and a portion of the second set of leads not covered by the mold compound form terminals for the microelectronic device package.

In a described example, an apparatus includes: a package substrate having a first set of leads spaced from a first die pad configured for mounting semiconductor devices, and having a second set of leads spaced from a second die pad configured for mounting additional semiconductor devices, the first die pad and the first set of leads spaced from the second die pad and the second set of leads, the space between the first die pad and the second die pad forming an isolation barrier; semiconductor devices mounted to a device side surface of the first die pad and at least one semiconductor device mounted to the device side surface of the second die pad; electrical connections formed between bond pads of the semiconductor devices mounted to the first die pad and the first set of leads, and formed between bond pads of the at least one semiconductor device mounted to the second die pad and the second set of leads; a ceramic interposer mounted to an opposite side surface of the package substrate opposite the device side surface and in thermal contact with at least the first die pad; and mold compound covering the semiconductor devices mounted to the first die pad, the at least one semiconductor device mounted to the second die pad, the electrical connections, a portion of the ceramic interposer, portions of the first set of leads, and portions of the second set of leads. The mold compound forms a body of a microelectronic device package, the ceramic interposer having a surface exposed from the mold compound, the first set of leads and the second set of leads having portions exposed from the body to form terminals of the microelectronic device package.

In a further described example, a microelectronics device package includes: a package substrate having a first set of leads spaced from a first die pad that is configured for mounting semiconductor devices, and having a second set of leads spaced from a second die pad configured for mounting additional semiconductor devices, the first die pad and the first set of leads spaced from the second die pad and the second set of leads, the space between the first die pad and the second die pad configured to form an isolation barrier; semiconductor devices mounted to a device side surface of the first die pad and at least one semiconductor device mounted to a device side surface of the second die pad; wire bond connections formed between bond pads of the semiconductor devices mounted to the first die pad and the first set of leads, and additional wire bond connections formed between bond pads of the at least one semiconductor device mounted to the second die pad and the second set of leads; a ceramic interposer mounted to an opposite side surface of the package substrate opposite the device side surfaces of the first die pad and the second die pad, and in thermal contact with the first die pad and the second die pad; and mold compound covering the semiconductor devices mounted to the first die pad, the at least one semiconductor device mounted to the second die pad, the electrical connections, a portion of the ceramic interposer, portions of the first set of leads, and portions of the second set of leads. The mold compound forms a body of a microelectronic device package, the ceramic interposer having a surface exposed from the mold compound, the first set of leads and the second set of leads having portions exposed from the body to form terminals of the microelectronic device package.

### BRIEF DESCRIPTION OF THE DRAWINGS

FIGS. 1A-1B illustrate, in a projection view and a close-up projection view, respectively, semiconductor dies on a semiconductor wafer and an individual semiconductor die.

FIGS. 2A-2C illustrate, in a top side projection view, a rear side projection view, and a cross-sectional view, respectively, a microelectronic device package of an example arrangement.

FIGS. 3A-3E illustrate, in cross-sectional views, portions of a microelectronic device package of an example arrangement.

FIG. 4 illustrates, in another cross-sectional view, a microelectronic device package of an alternative arrangement.

FIG. 5 illustrates, in a flow diagram, selected steps of a method for forming the arrangements.

### DETAILED DESCRIPTION

Corresponding numerals and symbols in the different figures generally refer to corresponding parts, unless otherwise indicated. The figures are not necessarily drawn to scale.

Elements are described herein as “coupled.” The term “coupled” includes elements that are directly connected and elements that are indirectly connected, and elements that are electrically connected even with intervening elements or wires are coupled.

The term “semiconductor device” is used herein. A semiconductor device can be a discrete semiconductor device such as a bipolar transistor, a few discrete devices such as a pair of power FET switches fabricated together on a single semiconductor die, or a semiconductor device can be an integrated circuit with multiple semiconductor devices such as the multiple capacitors in an A/D converter. The semiconductor device can include passive devices such as resistors, inductors, filters, sensors, or active devices such as transistors. The semiconductor device can be an integrated circuit with hundreds or thousands of transistors coupled to form a functional circuit, for example a microprocessor or memory device. When semiconductor devices are fabricated on a semiconductor wafer and then individually separated from the semiconductor wafer, the individual units are referred to as “semiconductor dies.” A semiconductor die is also a semiconductor device.

The term “passive component” is used herein. As used herein, a passive component is a component without active devices, for example, a resistor, capacitor, inductor, coil, diode, or sensor. Examples useful in the arrangements include capacitors, resistors, inductors, transformers, or coils.

The term “ceramic interposer” is used herein. A ceramic interposer is a piece of ceramic material placed between elements, in the example arrangements the ceramic interposer is placed between a package substrate and mold compound that forms a body for a microelectronic device package. In the arrangements the ceramic interposer is placed on a surface of a package substrate opposite a device side surface of the package substrate, so that the ceramic interposer is in thermal contact with components mounted on the device side surface of the package substrate. In examples, the ceramic interposer can be one of alumina (aluminum oxide, or Al₂O₃₎ or aluminum nitride (AlN) and can be provided as rectangular pieces with opposing planar surfaces arranged for mounting to the package substrate. In particular examples, after mold compound is applied to form the package body for a microelectronic device package including the ceramic interposer, a surface of the ceramic interposer is exposed from the mold compound to provide thermal dissipation.

The terms “electrical isolation,” “isolation,” “reinforced isolation” and “robust isolation” are used herein. In the example arrangements, a first set of leads and a second set of leads extend from the body of a device package. The first set of leads is configured for coupling to a first voltage domain. The second set of leads is configured for coupling to a second voltage domain. The first voltage domain and the second voltage domain have different and unrelated grounds that are physically and electrically isolated from one another. In operation, the first set of leads and the second set of leads may therefore be at greatly different potentials; a voltage difference between the first set of leads and the second set of leads can be tens, hundreds, or thousands of volts. To ensure the devices operate properly and to prevent damage to the devices within the device package, electrical isolation is required within the package. The term “isolation” means that, up to a maximum voltage that can be thousands of volts, the two voltage domains do not electrically couple. The isolation is accomplished by a physical space within the device between the first set of leads and the second set of leads that is sufficiently large to prevent arcing or capacitively coupling between the first set of leads and the second set of leads. This can be referred to as an “isolation barrier.” Because the device package is a molded package, the space can be filled with mold compound. The terms “isolation”, “electrical isolation”, “robust isolation” and “reinforced isolation” as used herein mean that the device package includes a spatial distance between the leads of the first voltage domain and the second voltage domain and that the materials and leads are arranged to prevent unwanted electrical coupling between the first set of leads (and devices coupled to the first set of leads) and the second set of leads (and devices coupled to the second set of leads.) Signals or current can be intentionally transferred across the isolation barrier, for example using a transformer or a signal isolator device that uses capacitive coupling to transmit signals across the isolation barrier without electrical coupling.

The term “microelectronic device package” is used herein. As used herein, a microelectronic device package has at least one semiconductor die electrically coupled to terminals and has a package body that protects and covers the semiconductor die. The microelectronic device package can include additional semiconductor dies or additional elements. For example, in example arrangements multiple semiconductor die components are included. In example arrangements, multiple semiconductor dies can be packaged together using an isolation package substrate. The semiconductor die or dies is/are mounted to die pads on the isolation package substrate that are isolated from one another and spaced apart. An isolation device that uses a dielectric material and capacitive coupling, or that uses an integral transformer, can be used to couple power or data signals between isolated semiconductor dies across the isolation barrier within the microelectronic device package.

The term “package substrate” is used herein. A package substrate is a substrate arranged to receive a semiconductor die and in the illustrated examples, other components, and to support the semiconductor die in a completed semiconductor device package. Package substrates useful with the arrangements include conductive leadframes, molded interconnect substrates (MIS), partially etched leadframes, pre-molded leadframes (PMLFs), embedded trace substrates (ETS), and multilayer package substrates. In an example arrangement, an isolation package substrate includes a conductive leadframe with multiple die pads, the die pads are spaced apart and are electrically isolated from one another. Leads of the isolation package substrate are configured to be coupled to a first voltage domain and to a second voltage domain, and the leads that are associated with the first voltage domain are isolated from the leads that are associated with the second voltage domain.

The term “shrink small outline package” or “SSOP” is used herein. A shrink small outline package is a microelectronic device package that has a reduced size when compared to a “small outline package” or SOP. A shrink small outline package has leads that extend from a mold compound package body to form terminals, the SSOP package has a lead-to-lead pitch of less than 1 millimeter. In an example arrangement, an SSOP microelectronic device package has a package length of about 10.3 millimeters, with a package body width of about 7.5 millimeters, and a thickness of about 2.28 millimeters, a size less than an SOP or than a small outline integrated circuit (SOIC) package used in prior approaches formed without use of the arrangements. Use of the arrangements allows SSOP packages to be used that include robust isolation.

In packaging microelectronic and semiconductor devices, mold compound may be used to partially cover a package substrate, to cover the package substrate, to cover passive components, to cover semiconductor dies, and to cover the electrical connections made to the package substrate. This molding process can be referred to as an “encapsulation” process, although portions of the package substrates are not covered in the mold compound during encapsulation; for example, terminals can be formed by portions of conductive leads that are exposed from the mold compound. The terminals are configured for electrical connections to the microelectronic device package. Encapsulation is often a compressive molding process, where a thermoset mold compound such as an epoxy resin can be used. A room temperature solid or powdered epoxy resin mold compound can be heated to a liquid state, and then molding can be performed by pressing the liquid mold compound into a mold through runners or channels. Transfer molding can be used. Unit molds shaped to surround an individual device may be used, or a block molding process may be used, to form multiple packages simultaneously for several devices from mold compound. The devices to be molded can be provided in an array or matrix of several, hundreds or even thousands of devices in rows and columns that are then molded contemporaneously.

After the molding process is complete, the individual microelectronic device packages are cut apart from each other in a sawing operation. A mechanical saw is used to cut through the mold compound and package substrate material in saw streets formed between the devices. Portions of the package substrate leads that are exposed from the mold compound package to form terminals for the microelectronic device packages. In the example arrangements, after a transfer molding process forms the body of the microelectronics device package from mold compound, a surface of the ceramic interposer is exposed from the mold compound to allow for thermal dissipation. The ceramic interposer thermally contacts the die pads while maintaining electrical isolation between them, as it is an electrical insulator.

The term “scribe lane” is used herein. A scribe lane is a portion of semiconductor wafer between semiconductor dies. Sometimes in related literature the term “scribe street” is used. Once semiconductor processing is finished and the semiconductor devices are complete, the semiconductor devices are separated into individual semiconductor dies by severing the semiconductor wafer along the scribe lanes. The separated dies can then be removed and handled individually for further processing. This process of removing dies from a wafer is referred to as “singulation” or sometimes referred to as “dicing.” Scribe lanes are arranged on four sides of semiconductor dies and when the dies are singulated from one another, rectangular semiconductor dies are formed.

The term “saw street” is used herein. A saw street is an area between molded electronic devices used to allow a saw, such as a mechanical blade, laser, or other cutting tool to pass between the molded electronic devices to separate the devices from one another. This process is another form of singulation. When the molded electronic devices are provided in a strip with one device adjacent to another device along the strip, the saw streets are parallel and normal to the length of the strip. When the molded electronic devices are provided in an array of devices in rows and columns, the saw streets include two groups of parallel saw streets, the two groups are normal to each other, and the saw will traverse the molded electronic devices in two different directions to cut apart the packaged electronic devices from one another in the array.

In an example arrangement, a ceramic interposer is mounted to the isolation package substrate, the ceramic interposer is mounted on a surface of the die pads of the package substrate opposite the device mounting areas. The elements are then covered or partially covered with mold compound, which can be an epoxy resin mold compound that can include fillers to enhance thermal conductivity. The ceramic interposer is thermally conductive and, in an example arrangement, has a surface exposed from the mold compound that forms the body of the microelectronic device package. The exposed surface of the ceramic interposer forms a ceramic thermal pad that dissipates heat from the microelectronics device package during operation. Additional thermal dissipation can be achieved by use of convection, by forced air cooling, by circulation of a cooling gas or liquid, or by mounting a heat sink to the ceramic interposer to further accelerate thermal dissipation. Because the exposed portion of the ceramic interposer is an electrical insulator, the creepage distance required for the isolation provided by the microelectronics device package is reduced (when compared to exposed portions of electrically conductive die pads used in prior approaches without the arrangements). This feature of the arrangements enables use of a smaller package size and results in reduced board area (compared to a device package formed without use of the arrangements) while maintaining a robust isolation characteristic.

In an example arrangement, multiple components are mounted to the die pads, either to a first die pad or to another die pad isolated from the first die pad and are mounted with bond pads on the semiconductor dies facing away from the die pads. Wire bonding processes using bond wire form wire bond connections between the bond pads and conductive portions of the leads. The isolation package substrate is then inverted so that the bond pads on the semiconductor dies face toward a board side of the package substrate. A ceramic interposer is mounted on the opposite side of the isolation package substrate, facing away from the board side of the package substrate.

Use of a ceramic interposer with the isolation package substrate in the arrangements enables the integration of the passive components and the semiconductor dies in a microelectronic device package with an isolation barrier, while allowing for a smaller package size than prior approaches, and yet still meeting the minimum creepage distance requirements for robust isolation. The microelectronic device package of the arrangements is relatively simple to assemble in packaging processes using known tools and methods and has increased reliability and performance over prior approaches.

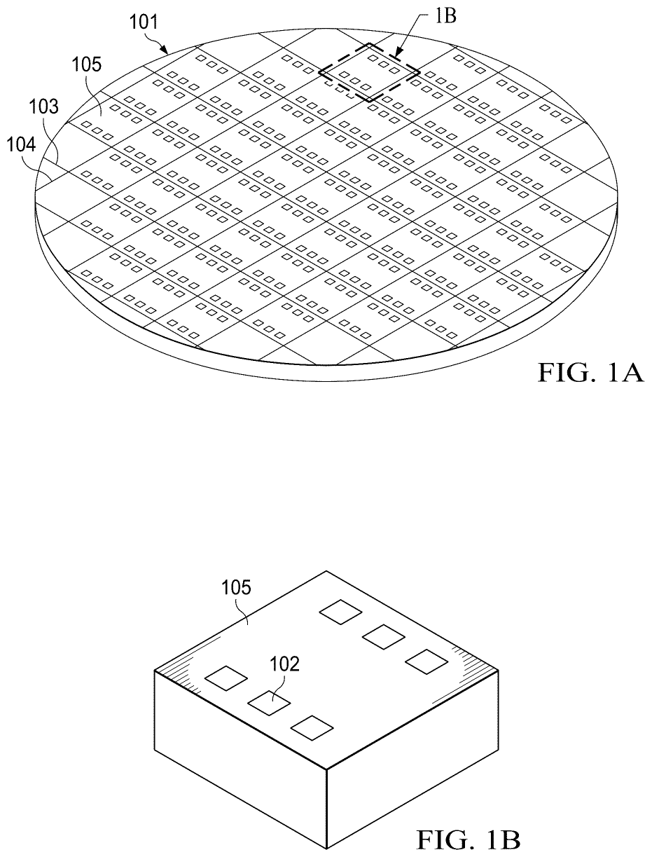

FIGS. 1A and 1B illustrate, in two projection views, a semiconductor wafer having semiconductor die devices formed on it that are configured for wire bonding, and an individual semiconductor die from the wafer configured for wire bonding and face-up mounting, respectively. In FIG. 1A, semiconductor wafer 101 is shown with an array of semiconductor dies 105 formed in rows and columns on a surface. The semiconductor dies 105 can be formed using processes in a semiconductor manufacturing facility, including ion implantation, doping, anneals, oxidation, dielectric and metal deposition, photolithography, pattern, etch, chemical mechanical polishing (CMP), electroplating, and other processes for making semiconductor devices. Scribe lanes 103 and 104, which are perpendicular to one another, and which run in parallel groups across the wafer 101, separate the rows and columns of the completed semiconductor dies 105, and provide areas for dicing the wafer 101 to separate the semiconductor dies 105 from one another.

FIG. 1B illustrates a single semiconductor die 105 taken from semiconductor wafer 101. Semiconductor die 105 includes bond pads 102, which are conductive pads that are electrically coupled to devices (not shown) formed in the semiconductor die 105. Not shown for clarity of illustration are under-bump metallization (UBM) portions which can be formed over the bond pads 102 to improve plating and adhesion between the bond pads and ball bonds of bond wire to be formed on the bond pads 102.

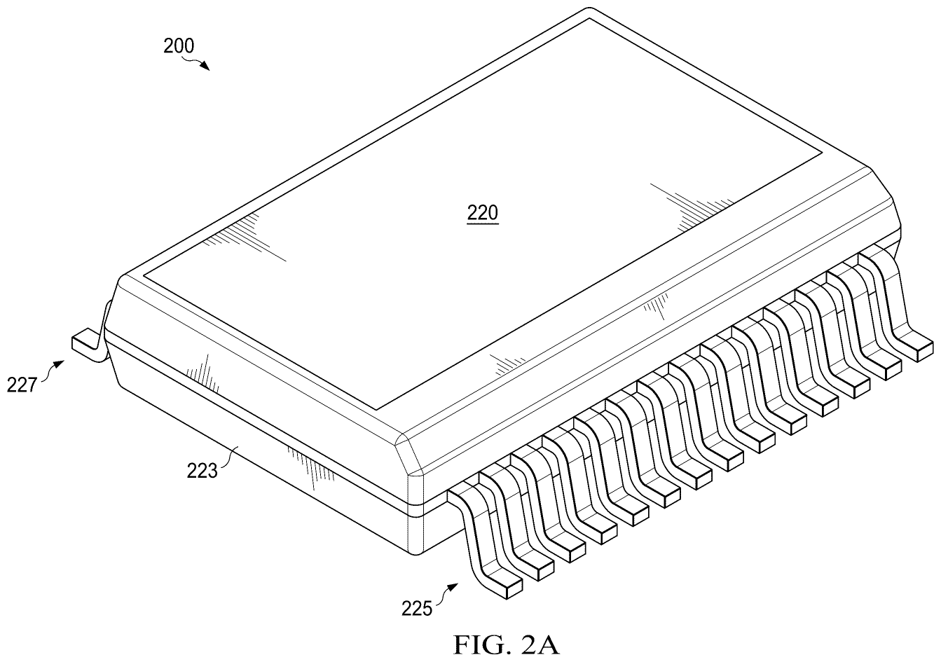

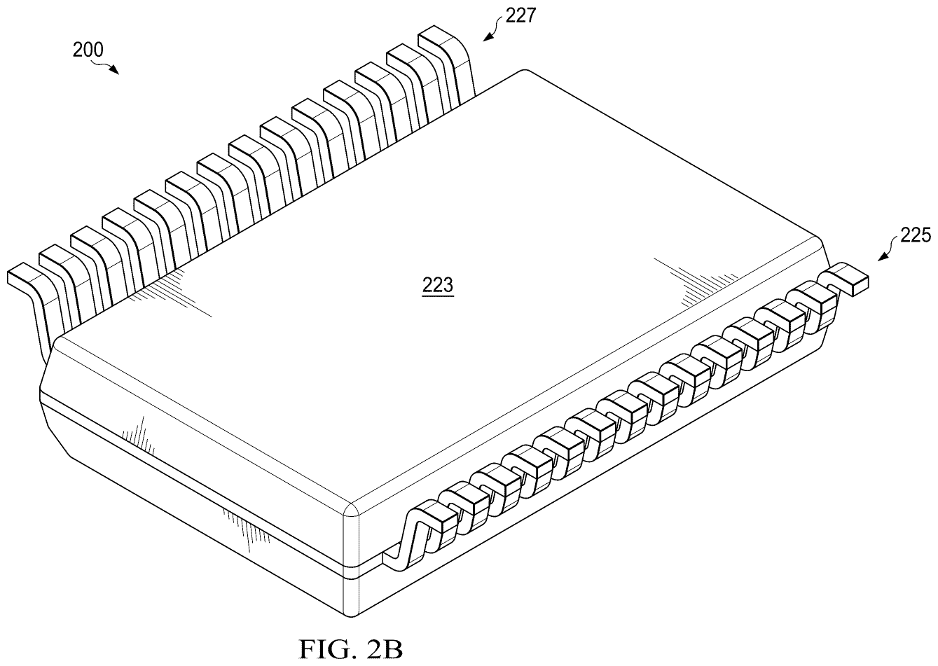

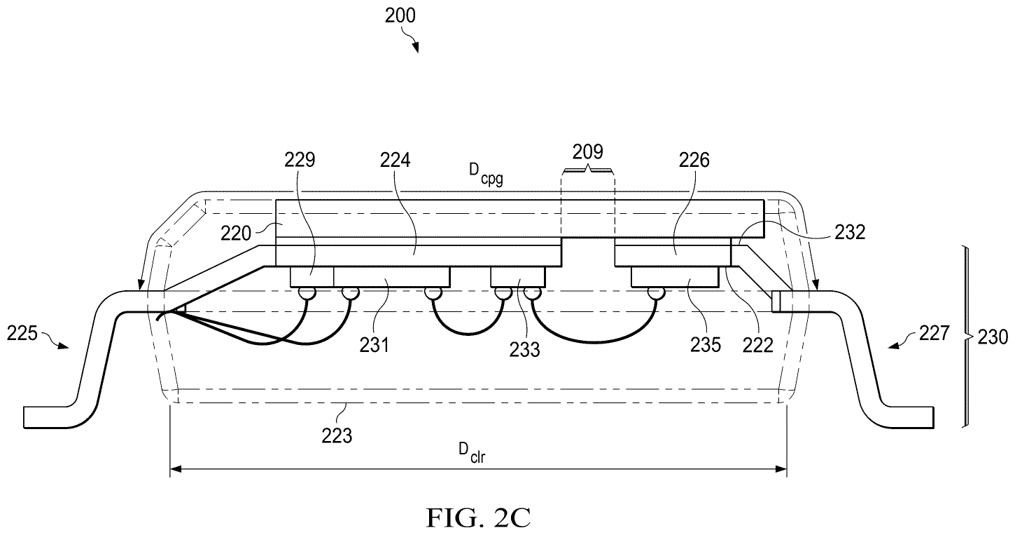

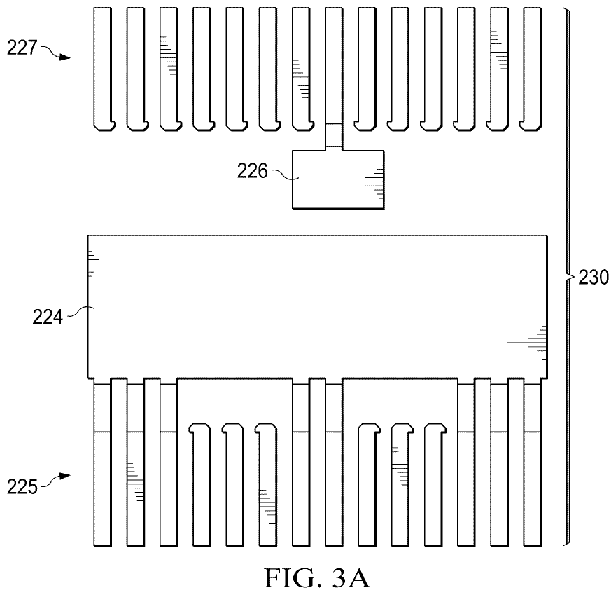

FIGS. 2A-2B illustrate, in a projection view and a cross-sectional view, respectively, a microelectronic device package 200 that can be used with an arrangement. In FIG. 2A, a microelectronic device package 200 is shown in a projection view from a top side surface. In the illustrated example, the microelectronic device package 200 is a shrink small outline package (SSOP), which is smaller than a small outline integrated circuit (SOIC) package or small outline package (SOP) used in prior approaches. The body of the microelectronic device package 200 is formed by mold compound 223. A first set of leads 225 and a second set of leads 227 are shown extending from a middle portion of the body of the package formed by mold compound 223. In the illustrated example the leads are shaped in a “gull wing” shape for use in surface mounting to a system board, for example using processes for surface mounting technology (“SMT.”) Leads 225 are arranged to be coupled to a first voltage domain, and leads 227 (more visible in FIG. 2B, as these leads are partially obscured in FIG. 2A) are configured to be coupled to a second voltage domain that is isolated from the first voltage domain.

In FIG. 2B, a projection view taken from the bottom or board side surface of the microelectronic device package 200 is shown. Leads 225 and 227 are shown on opposite sides of the body formed by mold compound 223. In an example the first set of conductive leads 225 arranged to be coupled to a first voltage domain, while the second set of conductive leads 227 is arranged to be coupled to a second voltage domain that is isolated from the first voltage domain. The leads 225 and 227 extend away from the package body formed by mold compound 223 and are shaped to form terminals with “feet” at the outward ends for surface mounting. Other lead shapes can be used. An advantage of “gull-wing” shaped leads is that these leads allow for some slight movement, for example due to movement of a board or of a device during package mounting, or due to thermal expansion of components while in operation, the slight movement of the leads can occur without causing a solder joint failure, thereby increasing board level reliability (“BLR.”)

FIG. 2C illustrates, in a cross-sectional view, the microelectronic device package 200 of FIGS. 2A-2B. Package substrate 230, in this example a conductive leadframe, includes the first set of leads 225 and the second set of leads 227 that extend from the body of the microelectronic device package 200 formed by mold compound 223. Semiconductor dies or passive components 229, 231, 233 and 235 are shown mounted on a device side surface 222 of the package substrate 230 and facing the board side of the microelectronic device package 200. The package substrate 230 has a split die pad design for providing electrical isolation, with components 229, 231, and 233 shown mounted on a first die pad 224, and the semiconductor die 235 mounted on a second die pad 226. The space and materials between the leadframe die pad elements form an isolation barrier, numbered 209 in FIG. 2C. A ceramic interposer 220 is shown mounted on the package substrate 230 on a top side surface 232 which is opposite the device side surface 222 where the semiconductor dies or components 229, 231, 233, 235 are mounted. The ceramic interposer 220 has a surface exposed from the mold compound 223 facing upwards (as the elements are oriented in FIG. 2C). In useful example arrangements, the ceramic interposer 220 is formed of a thermally conductive ceramic material that is one of alumina (aluminum oxide), aluminum nitride, or zirconium oxide. In a particular example, ceramic interposer 220 is alumina (aluminum oxide). In an additional alternative example, the ceramic interposer 220 is aluminum nitride. In yet another additional alternative example, the ceramic interposer 220 is zirconium oxide. Importantly, in the arrangements, the ceramic interposer 220 is a thermal conductor but is also an electrical insulator, so that the ceramic interposer 220 can be in thermal contact with the semiconductor dies or components 229, 231, 233, and 235 without making electrical contact to the devices, and without creating a leakage path between the devices on either side of the isolation barrier. The exposed surface of the ceramic interposer 220 forms a ceramic thermal pad for the microelectronic device package 200.

In FIG. 2C, two distances are shown, a clearance distance labeled “Dclr”, and a creepage distance labeled “Dcpg.” In microelectronic device packages such as the illustrated example 200 that provide electrical isolation between certain leads and which provide isolation between the components arranged to be coupled to different voltage domains with isolated grounds, these distances must be greater than a minimum spacing to prevent arcs forming between conductive leads at different potentials (clearance distance) and to prevent a leakage path from forming as a body effect current between leads of the different domains over the insulator material (a creepage distance over the body of the microelectronic device package). The creepage distance “Dcpg” can be adversely impacted by a conductor exposed from the mold compound, as in a prior approach. Advantageously, in the arrangements, the use of the ceramic interposer 220 to provide thermal dissipation does not impact the creepage distance Dcpg, because the ceramic interposer 220 is an insulator. This is in sharp contrast to exposed conductive thermal pads or exposed portions of conductive die pads used in prior approaches, which expose electrically conductive material on the surface of the microelectronic device package, therefore requiring a larger package size to meet the minimum creepage and clearance distances. Use of the arrangements advantageously enables a smaller microelectronic device package size (when compared to prior approaches for isolation packages) while maintaining the minimum creepage distance and minimum clearance distance required for robust isolation.

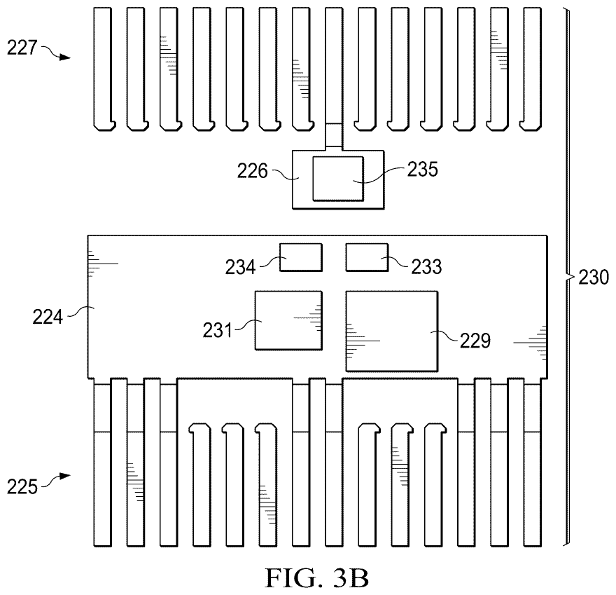

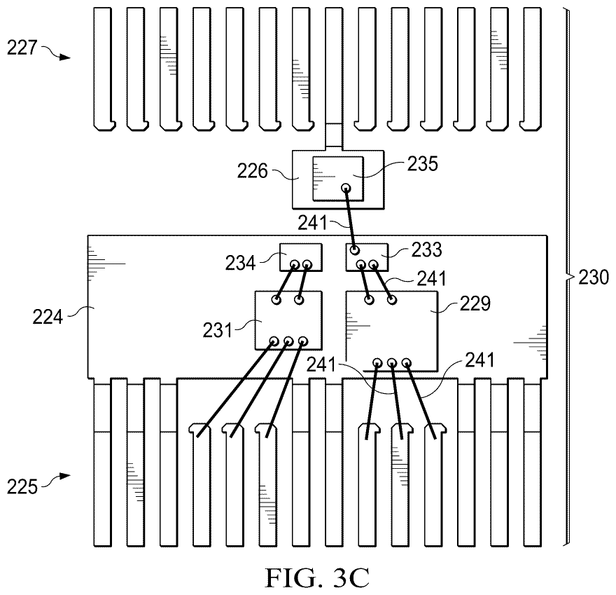

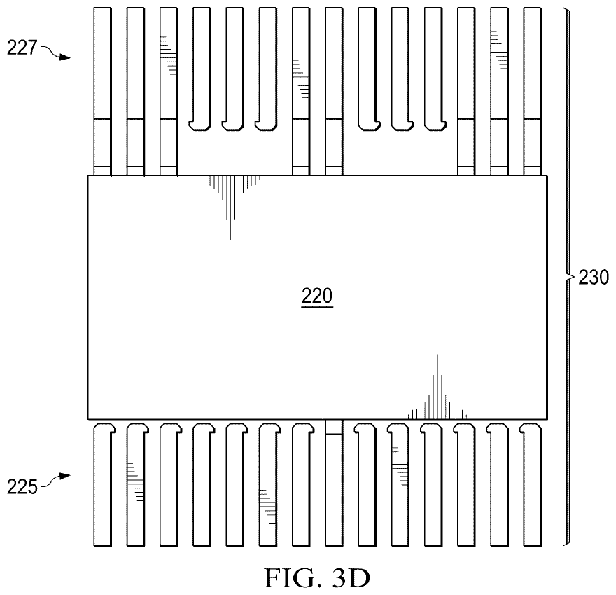

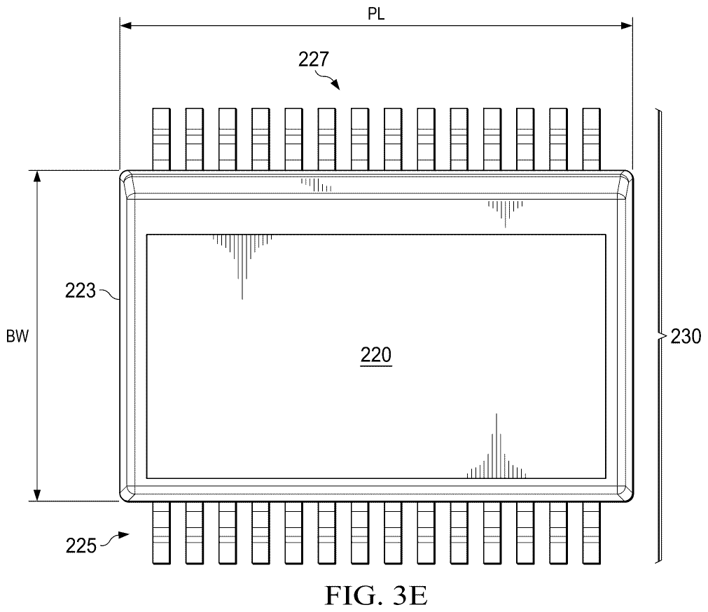

FIGS. 3A-3E illustrate, in a series of plan views, steps used to form a microelectronic device package of an arrangement. In the series of plan views a single unit package substrate is shown to illustrate the process steps. However, in a production process, the package substrates can be provided as multiple units temporarily joined together in an array or grid format, with unit package substrates arranged in rows and columns, to enable gang production during the packaging processes, increasing throughput and lowering costs per unit. The package substrates used in the example arrangement shown in FIGS. 3A-3E start with a downset form, which is then inverted during the packaging process so that the semiconductor dies in the completed microelectronic device package are in an “upset” configuration and positioned towards the top surface of the package body formed by the mold compound. A downset package substrate has die mounting areas on die pads that lie in a plane that is lower than a parallel plane formed by the leads extending away from the die mounting areas. The downset is not visible in the plan views of FIGS. 3A-3E but is visible in FIG. 2C. In FIG. 2C, the die pads 224, 226 lie in a first horizontal plane that is offset from the horizontal plane that the leads lie in (when the elements are in a normal orientation as shown), which has certain advantages as are explained further below.

In FIG. 3A, a unit package substate 230 is shown viewed from a device side surface (note that in FIG. 3A the package substrate 230 is oriented with the device side surface facing upwards, for ease of processing, in contrast the device side surface 222 in the microelectronic device package 200 of FIG. 2C is shown oriented downwards, or facing a board side of the microelectronic device package 200). In the illustrated example of FIG. 3A, the package substrate 230 is shown implemented using a conductive leadframe. Copper, plated copper, partially plated copper, steel, and stainless-steel materials can be used, in a useful example copper or Alloy 42 can be used. The leadframe can be spot plated at locations where bond wires will be bonded to the leadframe surface, using plating materials that enhance the wire bonds, such as silver, nickel, gold, palladium, tin, and combinations of these. The leadframe can be uniformly plated over the entire surface, instead of being spot plated. The leads or portions of the leads can be plated to reduce corrosion or tarnish and to reduce or prevent ion diffusion using nickel, gold, palladium or combinations of these, such as electroless nickel immersion gold (sometimes referred to as “ENIG” plating) or electroless nickel, electroless palladium, and immersion gold (sometimes referred to as “ENEPIG” plating).

In FIG. 3A, unit package substrate 230 has a first set of leads 225 extending away from a middle portion of the leadframe, and a first die pad 224 is shown connected to the first set of leads 225. Although it is not visible in the plan view of FIG. 3A, the first die pad 224 is downset from the first set of leads 225. The first die pad 224 is arranged to mount at least one semiconductor die, (see FIG. 3B described below, where there are several semiconductor dies or components shown.) The first set of leads 225 and the first die pad 224 are spaced from and will be electrically isolated from the second set of leads 227 and the second die pad 226, which can be used to mount at least one or several components including semiconductor dies and passive components. The first set of leads 225 and the first die pad 224 are arranged to be coupled to a first voltage domain with a first ground, and the second set of leads 227 and the second die pad 226 are arranged to be coupled to a second voltage domain with a second ground that is isolated from the first ground. Because the first ground and the second ground are electrically isolated from each other, voltages can occur between the first set of leads and the second set of leads in tens, hundreds or even thousands of volts, so that for the microelectronics device package to be reliable and have a useful lifetime, robust electrical isolation is needed between the first set of leads 225 and the second set of leads 227, and between components mounted on the first die pad 224 and those components mounted to the second die pad 226. Use of the arrangements enables robust isolation with enhanced thermal dissipation while providing these elements in a smaller package size (when compared to microelectronic device packages including isolation in prior approaches).

FIG. 3B illustrates, in another plan view from the device side surface, the package substrate 230 after components 229, 231, 233, 234, and 235 are mounted on the first die pad 224 and second die pad 226 using a die mounting process. The components can include semiconductor dies and passive components, for example. In an example application, which can include components arranged as part of a universal serial bus power delivery (USB-PD) device, at least one of the semiconductor dies can be a switching power device, in one example a gallium nitride field effect transistor (GaN FET) commercially available from Texas Instruments, Incorporated of Dallas, Texas, USA can be used. The GaN FET includes a power transistor with a low on-resistance drain-to-source current path arranged to deliver current from a voltage to a load. In operation this type of switching power semiconductor device can generate substantial heat. To provide reliable packaging for power devices, thermal dissipation is needed in the microelectronics device package for at least the power FET device 229. Thermal dissipation that transfers thermal energy from the other components is also beneficial and increases performance. In the illustrated examples, the semiconductor die 231 can be a primary side controller device that is coupled to the power FET device 229, while the dies 233 and 234 can be a resistor network, and an isolation die that uses a dielectric between two conductors to form a signal isolation device. The semiconductor die 235 can be a second side controller device, which is isolated from the other dies in the package.

In FIG. 3B, the devices 229, 231, 233, 234 are shown mounted on the die pad 224 using, for example, a die attach film, die attach epoxy, or die attach paste. In an example a conductive die attach film (CDAF) can be used, alternatively a non-conductive die attach film (NCDAF) can be used. Ink jet printed or drop-on-demand die attach materials can be used. Another semiconductor die 235 is shown mounted on the second die pad 226, which is spaced from and will be electrically isolated from the first die pad 224. Again, conductive, or non-conductive die attach film, die attach epoxy or paste can be used to mount the die 235.

In a particular example arrangement, semiconductor die 229 can be a power switching device that will carry current to a load from a supply voltage, and which can generate substantial heat in operation. Thermal dissipation is needed for the reliable operation of at least the semiconductor die 229 in a microelectronics device package. However, in alternative example arrangements, other ones of the components 234, 233, 231, and 235 may also benefit from additional thermal dissipation. Advantageously, in the example illustrated arrangements, thermal dissipation is provided to all the components. In additional example arrangements, other circuitry can be implemented by mounting various components on the package substrate 230, for example a DC-DC converter can be provided.

FIG. 3C illustrates, in a further plan view, the elements of FIG. 3B after a wire bonding operation makes electrical connections by forming wire bonds between the semiconductor dies 229, 231, 233, 234 and 235, and other components, and between the semiconductor dies and other components and conductive leads of the package substrate 230. In a wire bonding operation useful with the arrangements, electrical connections are formed using bond wire coupled between bond pads on semiconductor dies or other components, and conductive leads of the package substrate, such as leads of the leadframe. In an example process, automated wire bonding equipment can rapidly make hundreds of bond wire connections in succession, and in a production mode, can move from unit device to unit device on a grid or array of unit devices, completing the necessary wire bonds very quickly.

In an example ball bonding process that can be used with the arrangements, a wire bonding tool includes a hard capillary of ceramic or another insulator that has a central opening. A supply of bond wire is arranged so that the end of the bond wire extends from a central opening in the capillary. A wire bonding cycle begins by forming a ball on the end of the bond wire, in example processes this can be done using a flame or by using an electronic arc to melt the exposed end of the bond wire, forming a molten ball. The capillary is then positioned to push the molten ball onto a bond pad. In the automated wire bonding tool, mechanical pressure, heat, and ultrasonic vibration can be applied to perform thermosonic wire bonding, to attach the molten ball to the bond pad. The capillary then moves away from the ball bond on the bond pad while allowing the bond wire to extend through the capillary and from the ball bond, and the capillary is then positioned over a conductive portion of a lead of the package substrate. Again, using mechanical pressure and ultrasonic energy, a stitch bond is formed on the lead, and as the capillary moves a short distance away from the stitch bond, the extending bond wire is cut or broken to leave a free end of the bond wire extending from the capillary. The free end of the bond wire is ready for another cycle. This process is referred to as “ball and stitch” wire bonding. Alternative approaches include first forming a ball on a conductor such as a bond pad, forming a second ball bond and then extending the bond wire to the first ball, and forming a “stitch on ball” bond on the first ball. The bond wires can be of copper, palladium coated copper (PCC), aluminum, gold, or other conductive bond wire material. When the wire bonding process uses copper or copper-based bond wire, an anoxic environment may be created in the automated wire bonding tool to reduce or prevent corrosion or tarnish of the copper bond wires, which can be accelerated at the higher temperatures used in wire bonding tools. Alternatives to wire bonding with bond wires include ribbon bonding where conductive ribbons are placed over and bonded to the components using mechanical pressure.

In FIG. 3C, the elements of FIG. 3B are shown after a wire bonding step. Wire bonds 241 are shown connecting the semiconductor dies 229, 231, 234, 233, and 235 (or other components) to the leads of the package substrate 230, as well as to one another. The first set of leads 225 have wire bonds 241 connecting to the semiconductor dies and components 229, 231, 233, 234. The second set of leads 227 have wire bonds 241 connecting to the semiconductor die 235.

FIG. 3D illustrates, in a plan view, the package substrate 230 of FIG. 3C after an additional process step. In FIG. 3D, package substrate 230 has been rotated to an inverted position (with respect to FIG. 3C) so that the topside surface is now shown facing upwards, opposite the device side surface shown in FIG. 3A. (See, for example, the topside surface 232 in FIG. 2C, and the opposite device side surface 222 in FIG. 2C). A ceramic interposer 220 is shown mounted on the topside surface. In one example useful with the arrangements, a conductive die attach film (CDAF) can be deposited on the package substrate to mount the ceramic interposer 220. In another alternative arrangement, a non-conductive die attach film (NCDAF) can be deposited. Die attach materials including pastes, epoxies or solder can be deposited on the package substrate to attach the ceramic interposer. Because the ceramic interposer of the arrangements is an electrical insulator, either conductive or non-conductive die attach material can be used without creating a current leakage path between elements. The ceramic interposer 220 can also be mounted to the package substrate 230 using die attach epoxies or pastes, or by using solder. Film, tape, ink jet or drop on demand methods can be used to apply the die attach material. A cure process can be used to prepare the die attach material, and after mounting, an additional cure may be used to complete the mounting, depending on the die attach material chosen.

In example arrangements, the ceramic interposer 220 is formed of aluminum oxide (alumina, or Al₂O₃), aluminum nitride (AlN), or zirconium oxide (ZrO₂). In one approach a sheet of the ceramic interposer material can be cut to form pieces or appropriate size and mounted to the package substrates using pick and place tools to place the individual ceramic interposers on the unit package substrates. The ceramic interposer 220 can be sized to overlap both die pads 224, 226 on the package substrate 230 as shown in FIG. 2C. In an alternative approach, the ceramic interposer 220 can be sized to overlap only a selected component, for example the semiconductor die 229 in FIG. 3C, to provide thermal dissipation only to a power device. In the example arrangements shown in the figures, the ceramic interposer 220 is thermally coupled to multiple components and as an additional advantage of the arrangements, can be coupled to components on both die pads, that is on either side of an isolation barrier, which is possible because the ceramic interposer used in the arrangements is an electrical insulator.

FIG. 3E illustrates, in an additional plan view, the elements of FIG. 3D after an additional processing step. In FIG. 3E, mold compound 223 is shown covering a portion of the package substrate 230, the bond wires, the semiconductor dies or other components, and the die pads of the package substrate 230, while a surface of the ceramic interposer 220 is exposed from the mold compound 223 on the top surface of the completed microelectronic device package 200. The exposed portion of the ceramic interposer 220 forms a ceramic thermal pad for the microelectronic device package 200. Portions of the leads of the package substrate 230 are covered by the mold compound 223, while the remaining portions extending from the mold compound 223 form terminals of leads 225, and of leads 227, the terminals are arranged to enable the microelectronic device package 200 to be mounted to a board or module and to be electrically connected to signals or power supplies. The leads 225, 227 have, in an example arrangement, “gull wing” shapes, as shown in the cross-sectional view of FIG. 2C. Gull wing shaped leads are arranged for surface mounting to a board or module, for example using solder in a surface mount technology (SMT) process. In a particular example, the microelectronic device package 200 can be a “shrink small outline package” (SSOP). In the particular example, the body width (labeled “BW” in FIG. 3E0 was about 7.5 millimeters, the package length (labeled “PL” was abut 10.3 millimeters, and the thickness of the microelectronic device package was about 2.286 millimeters, less than the body width of an SOP package used in a prior approach, and less area than an SOIC package used in another prior approach. The thermal performance of the microelectronic device package of the particular example was also improved over prior approaches. In a mechanical simulation, the figure of merit thermal resistance R_{θj-c} was about 4.9 degrees C./W; about a 300 percent improvement over the same figure of merit for previous packages formed without use of the ceramic interposer of the arrangements.

When the microelectronic device package is later mounted to a board or module, the ceramic interposer of the arrangements provides a thermal dissipation path for the internal components. Additional thermal dissipation can be provided by adding heat sinks or heat slugs mounted to the microelectronic device package 200, for example, thermal grease or another thermal interface material can be applied to the exposed surface of ceramic interposer 220 and a heat sink can then be physically attached to the microelectronic device package 200 to further increase thermal dissipation. Convection, forced air, circulating coolant or other cooling techniques can be applied to further enhance thermal dissipation from the microelectronic device package 200.

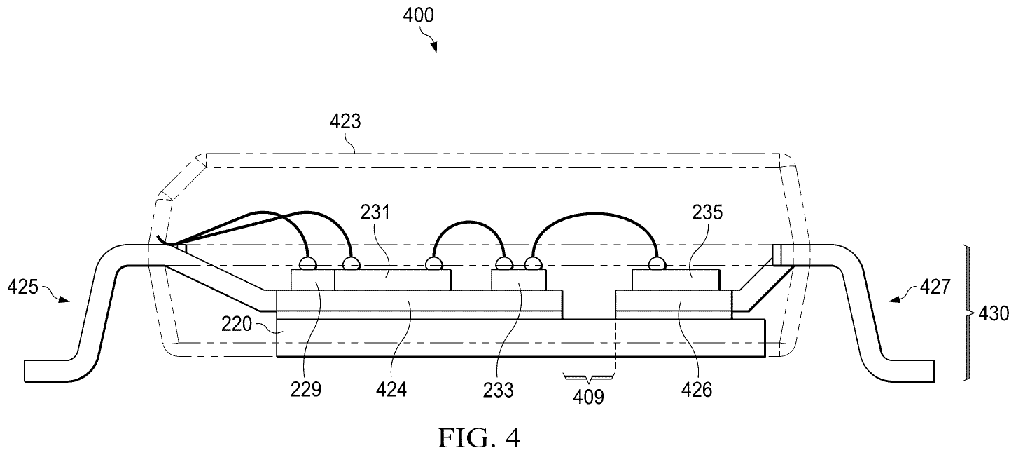

FIG. 4 illustrates, in a cross-sectional view, an alternative arrangement for a microelectronic device package 400. In FIG. 4, ceramic interposer 220 is mounted on the board side of a package substrate 430. The leads 425, 427 of the package substrate, for example a leadframe, are arranged in a “downset” configuration so that the die pads 424, 426 that are arranged for mounting the components 229, 231, 233 lie in a plane that is closer to the board side of the body of the microelectronic device package 400 formed by mold compound 423 than the middle portion, and in this alternative arrangement the ceramic interposer 220 is now mounted so that the ceramic interposer 220 has a surface exposed from the mold compound 423 on the board side of the microelectronic device package 400. The spacing between the die pads and the materials form an electrical isolation barrier numbered 409 between the elements. The leads 425, 427 are shown with “gull wing” shapes to enable mounting to a board or module using solder in a surface mount technology (SMT) process. The components 229, 231, 235 are the same as those used in the arrangement of FIG. 2C, and the ceramic interposer 220 is also the same as that used in the arrangement of FIG. 2C, however in this alternative arrangement, a different package substrate 430 is used to arrange the elements for board side cooling, instead of top side cooling. Thermal interface material can be used to couple the exposed portion of the ceramic interposer 220 to a thermal pad on the board or module, to further dissipate thermal energy. The arrangements of FIG. 4, and FIG. 2C, each provide the advantages that accrue due to use of the ceramic interposer in an isolation package, the ability to use a smaller microelectronic device package while still providing robust isolation between leads arranged to be coupled to isolated voltage domains.

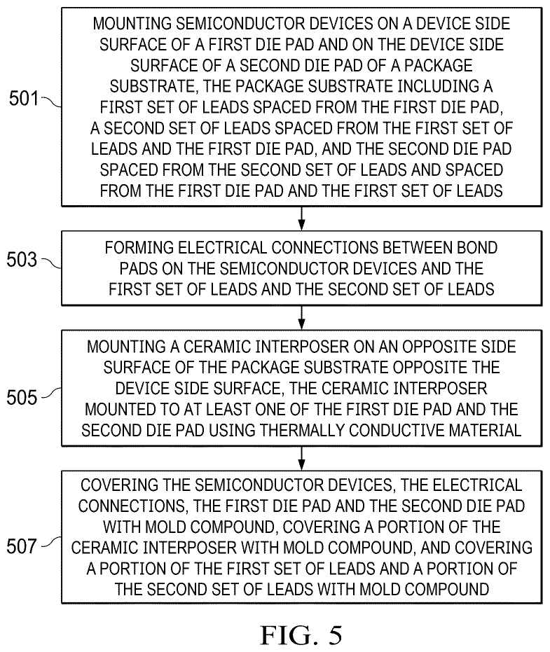

FIG. 5 illustrates, in a flow diagram, the steps used to form a microelectronic device package using the ceramic interposer in an example arrangement.

In FIG. 5 the method begins at step 501, by mounting semiconductor devices on a device side surface of a first die pad and on the device side surface of a second die pad of a package substrate, the package substrate comprising a first set of leads spaced from the first die pad, a second set of leads spaced from the first set of leads and the first die pad, and the second die pad spaced from the second set of leads and spaced from the first die pad and the first set of leads. (See, for example, FIGS. 3A-3B, package substrate 230, and semiconductor devices and components 231, 229, 233, 234, and 235 mounted on the first die pad 224 and on the second die pad 226).

At step 503, the method continues by forming electrical connections between bond pads on the semiconductor devices and the first set of leads and the second set of leads. (See, for example, wire bonds 241 shown in FIG. 3C).

At step 505, the method continues by mounting a ceramic interposer on an opposite side surface of the package substrate opposite the device side surface, the ceramic interposer mounted to at least one of the first die pad and the second die pad using thermally conductive material. (See, for example, ceramic interposer 220 shown in FIG. 3D).

At step 507, the method continues by covering the semiconductor devices, the electrical connections, covering a portion of the ceramic interposer with mold compound, and covering a portion of the first set of leads and a portion of the second set of leads with mold compound. (See, for example, mold compound 223 shown in FIG. 3E). After the method is complete, the mold compound forms a body of a microelectronic device package, the ceramic interposer having a surface exposed from the mold compound, and a portion of the first set of leads not covered by the mold compound and a portion of the second set of leads not covered by the mold compound form terminals for the microelectronic device package. (See, for example, FIG. 2C, ceramic interposer 220 exposed from the mold compound 223, and the first set of leads 225 and the second set of leads 227 forming terminals for the microelectronic device package 200.)

The use of the arrangements and methods provide microelectronic device packages including semiconductor dies and/or passive components that are isolated from one another by an isolation barrier to provide robust isolation with a ceramic interposer that provides thermal dissipation. Existing materials and assembly tools are used to form the arrangements, and the arrangements are relatively low in cost. The use of the arrangements allows microelectronic device packages including isolation barriers with smaller package sizes than packages formed without the arrangements, the ceramic interposers allowing for meeting creepage distance and clearance distance requirements for isolation in smaller packages.

Modifications are possible in the described arrangements, and other alternative arrangements are possible within the scope of the claims.

What is claimed is:

1. A method, comprising:
mounting semiconductor devices on a device side surface of a package substrate on a first die pad and on the device side surface of a second die pad of the package substrate, the package substrate further comprising a first set of leads spaced from the first die pad, a second set of leads spaced from the first set of leads and the first die pad, and the second die pad spaced from the second set of leads and spaced from the first die pad and the first set of leads, the first set of leads electrically isolated from the second set of leads;
forming electrical connections between bond pads on the semiconductor devices and the first set of leads and the second set of leads;
mounting a ceramic interposer on an opposite side surface of the package substrate opposite the device side surface, the ceramic interposer mounted to at least one of the first die pad and the second die pad using thermally conductive material; and
covering the semiconductor devices, the electrical connections, the first die pad and the second die pad with mold compound, covering a portion of the ceramic interposer with the mold compound, and covering a portion of the first set of leads and a portion of the second set of leads with the mold compound, the mold compound forming a body of a microelectronic device package, the ceramic interposer having a surface exposed from the mold compound, and a portion of the first set of leads not covered by the mold compound and a portion of the second set of leads not covered by the mold compound forming terminals for the microelectronic device package.

2. The method of claim 1, wherein mounting the ceramic interposer comprises mounting the ceramic interposer that is one of aluminum oxide, aluminum nitride, or zirconium oxide.

3. The method of claim 1, further comprising mounting at least one passive device on the first die pad.

4. The method of claim 1, wherein the opposite side surface of the package substrate faces away from a board side surface of the microelectronic device package, and the ceramic interposer has a surface exposed from the mold compound on a top side surface of the microelectronic device package opposite the board side surface of the microelectronic device package.

5. The method of claim 1, wherein the opposite side surface of the package substrate faces towards a board side surface of the microelectronic device package, and the ceramic interposer has a surface exposed from the mold compound on the board side surface of the microelectronic device package.

6. The method of claim 1, wherein the semiconductor devices mounted to the first die pad further comprise at least one power FET device, and the ceramic interposer is in thermal contact with the at least one power FET device.

7. The method of claim 1, wherein mounting the ceramic interposer further comprises depositing a conductive die attach film on the opposite side surface of the package substrate and mounting the ceramic interposer using the conductive die attach film.

8. The method of claim 1, wherein mounting the ceramic interposer further comprises depositing a non-conductive die attach film on the opposite side surface of the package substrate and mounting the ceramic interposer using the non-conductive die attach film.

9. The method of claim 1, and further comprising, after covering the semiconductor devices, the electrical connections, the first die pad and the second die pad with the mold compound, covering a portion of the ceramic interposer with the mold compound, and covering a portion of the first set of leads and a portion of the second set of leads with the mold compound, forming the exposed portions of the first set of leads and forming the exposed portions of the second set of leads into gull wing shapes.

10. The method of claim 9, wherein the microelectronic device package is a shrink small outline package (SSOP) with a lead-to-lead pitch of less than 1 millimeter.

11. The method of claim 1, wherein forming electrical connections further comprises wire bonding to form wire bond connections between bond pads on the semiconductor devices mounted on the first die pad and the first set of leads.

12. The method of claim 10, and further comprising forming wire bond connections between the semiconductor device mounted on the second die pad and the second set of leads.

13. The method of claim 1, wherein the package substrate further comprises a conductive leadframe with a space between the first die pad and the second die pad forming an electrical isolation barrier.

14. An apparatus, comprising:
a package substrate having a device side surface and having an opposite side surface, the package substrate comprising a first set of leads spaced from a first die pad configured for mounting semiconductor devices, and having a second set of leads spaced from a second die pad configured for mounting additional semiconductor devices, the first die pad and the first set of leads spaced from the second die pad and the second set of leads, the space between the first die pad and the second die pad forming an electrical isolation barrier;
semiconductor devices mounted to the device side surface of the first die pad and at least one semiconductor device mounted to the device side surface of the second die pad;
electrical connections formed between bond pads of the semiconductor devices mounted to the first die pad and the first set of leads, and formed between bond pads of the at least one semiconductor device mounted to the second die pad and the second set of leads;
a ceramic interposer mounted to the opposite side surface of the package substrate and in thermal contact with at least the first die pad; and
mold compound covering the semiconductor devices mounted to the first die pad, the at least one semiconductor device mounted to the second die pad, the electrical connections, a portion of the ceramic interposer, portions of the first set of leads, and portions of the second set of leads, the mold compound forming a body of a microelectronic device package, the ceramic interposer having a surface exposed from the mold compound, the first set of leads and the second set of leads having portions exposed from the body of the microelectronic device package to form terminals.

15. The apparatus of claim 14, wherein the ceramic interposer is one of aluminum oxide, aluminum nitride, and zirconium oxide.

16. The apparatus of claim 14, wherein the microelectronic device package is a shrink small outline package with a body width of less than 8 millimeters.

17. The apparatus of claim 14, wherein the ceramic interposer is mounted to the package substrate using a conductive die attach film (CDAF).

18. The apparatus of claim 14, wherein the ceramic interposer is mounted to the package substrate using a non-conductive die attach film (NCDAF).

19. The apparatus of claim 14, wherein the exposed surface of the ceramic interposer is exposed from a top side of the microelectronic device package.

20. The apparatus of claim 14, wherein the exposed surface of the ceramic interposer is exposed from a board side of the microelectronic device package.

21. A microelectronic device package, comprising:
a package substrate having a first set of leads spaced from a first die pad that is configured for mounting semiconductor devices, and having a second set of leads spaced from a second die pad configured for mounting additional semiconductor devices, the first die pad and the first set of leads spaced from the second die pad and the second set of leads, the space between the first die pad and the second die pad configured to form an electrical isolation barrier;
semiconductor devices mounted to a device side surface of the first die pad and at least one semiconductor device mounted to a device side surface of the second die pad;
wire bond connections formed between bond pads of the semiconductor devices mounted to the first die pad and the first set of leads, and additional wire bond connections formed between bond pads of the at least one semiconductor device mounted to the second die pad and the second set of leads;
a ceramic interposer mounted to an opposite side surface of the package substrate opposite the device side surfaces of the first die pad and the second die pad, and in thermal contact with the first die pad and the second die pad; and
mold compound covering the semiconductor devices mounted to the first die pad, the at least one semiconductor device mounted to the second die pad, the electrical connections, a portion of the ceramic interposer, portions of the first set of leads, and portions of the second set of leads, the mold compound forming a body of a microelectronic device package, the ceramic interposer having a surface exposed from the mold compound, the first set of leads and the second set of leads having portions exposed from the body of the microelectronic device package to form terminals.

22. The apparatus of claim 21, wherein the ceramic interposer has the surface exposed from the mold compound at the top side of the microelectronic device package.

23. The apparatus of claim 21, wherein the ceramic interposer has the surface exposed from the mold compound at a board side of the microelectronic device package.

24. The apparatus of claim 21, wherein the microelectronic device package is a shrink small outline package, and the body of the microelectronic device package has a body width of less than 8 millimeters.

25. The apparatus of claim 21, wherein the ceramic interposer is one of aluminum oxide, aluminum nitride, or zirconium oxide.
